(19) United States
(12) Patent Application Publication
(10) Pub. No.: US 2022/0365143 A1
(43) Pub. Date: Nov. 17, 2022

(54) CIRCUIT AND METHOD FOR MONITORING A DC LINK CAPACITOR

(71) Applicant: ebm-papst Mulfingen GmbH & Co. KG, Mulfingen (DE)

(72) Inventors: Sebastian SCHROTH, Kupferzell (DE); Markus WEINGART, Rottenburg (DE); Andreas KERSCHREITER, Eching (DE)

(73) Assignee: ebm-papst Mulfingen GmbH & Co. KG, Mulfingen (DE)

(21) Appl. No.: 17/620,856

(22) PCT Filed: Jun. 23, 2020
(86) PCT No.: PCT/EP2020/067506

§ 371 Date: Dec. 20, 2021

(30) Foreign Application Priority Data
Jun. 27, 2019 (DE) 10 2019 117 369.8

(51) Int. Cl. G01R 31/64

(52) U.S. Cl. CPC G01R 31/64

(57) ABSTRACT

The invention relates to a device and a method for monitoring a DC link capacitor (C_{ZK}) in an electrical DC link of a circuit (1) operated on a mains voltage V_{ac}, the circuit comprising a power factor correction filter (PFC) and an inverter (20), the DC link capacitor (C_{ZK}) to be monitored being between the power factor correction filter (PFC) and the inverter (20). During the operation of the circuit (1), the DC link capacitance C of the DC link capacitor (C_{ZK}) is determined at least at certain time intervals over the operating time by measuring a power ripple W of a DC link voltage V_{ZK}, which DC link voltage arises at the DC link capacitor (C_{ZK}), said power ripple pulsing at twice the frequency of the mains voltage, and the remaining service life or the service life end and/or usability end of the DC link capacitor (C_{ZK}) is determined, by means of an evaluation circuit (30), from the DC link capacitance C determined in this way.

### CROSS-REFERENCE TO RELATED APPLICATIONS

This application is a 371 U.S. National Stage of International Application No. PCT/EP2020/067506, filed on Jun. 23, 2020, which claims priority to German Application No. 102019117369.8, filed on Jun. 27, 2019. The entire disclosures of the above applications are incorporated herein by reference.

### DESCRIPTION

The present disclosure relates to an electrical circuit and to a method for monitoring a DC link capacitor in an electrical circuit, particularly in an electronic control circuit for an electronically commutated electric motor, or EC motor.

In electronic circuits of certain electrical devices, aluminum electrolytic capacitors, or alu-ELCOs, are often used as energy stores or DC link capacitors. One major disadvantage is that an aluminum electrolytic capacitor is subject to aging during operation. This is particularly due to vaporization or evaporation of its liquid electrolyte. Therefore, this constitutes the main factor that limits the service life of the device.

The rate of aging and thus the available operating time, for example, up to the end of the service life or useful life are dependent on various parameters. They include the respective ambient temperature and the current load of the electrolytic capacitor during operation.

Using suitable empirical calculation methods, it can theoretically be estimated when the end of the service life of a DC link capacitor will be reached. However, since it is a purely theoretically estimated end of life, this does not necessarily result in an immediate defect in the electrolytic capacitor, or the estimate can also be quite inaccurate.

Adequate functioning of the DC link capacitor in the respective device, and thus also of the device itself, may then persist for a certain time. Therefore, a theoretical service life calculation is too imprecise for practice.

Document DE 10 2016 004 774 A1 discloses an exemplary embodiment where a measurement is performed with the aid of an impressed direct current using a ramp-up in order to determine the DC link capacitance. However, the measurement is performed at the point in time between switch-on and charged DC link. It would be desirable, however, for a measurement to be performed during actual operation of the circuit.

Document DE 10 2004 036 211 A1 describes another method for determining the aging of an electrolytic capacitor. In doing so, the actual operating conditions should be taken into account. The electrolytic capacitor is charged by means of a switchable precharging resistor. A time constant of the precharging process is calculated in a specified manner by voltage measurements during a precharging process, which is then compared to a predetermined time constant. Any deviation determined is taken as a measure of the aging of the electrolytic capacitor.

One solution is known from document EP 2 637 030 A1 involving a measurement via high-frequency HF ripple based on the switching frequency of the commutation circuit. However, an additional circuit is required for this purpose.

A method and a device for determining the remaining service life of an electrolytic capacitor of a frequency converter are described in document DE 10 2004 035 723 A1, which is known from the prior art. The remaining service life of an electrolytic capacitor is then calculated using its calculated core temperature and a corresponding service life. The core temperature is determined with the aid of the measured ambient temperature and its calculated power loss. From the service life, a rate of aging is calculated in each case, which is integrated into an actual age and which, subtracted from the end of the service life, yields the respective remaining service life. The power loss is calculated as a function of a measured DC link voltage, a measured motor current, a determined motor voltage, the capacitance of the electrolytic capacitor, and its effective internal resistances. All in all, this leads to a sizable computational burden.

Finally, document DE 10 2004 052 977 A1 relates to another diagnostic method for determining the aging condition of a capacitor. In that method, a plurality of aging-dependent parameters of the capacitor are measured using different discharging processes.

The present disclosure is based on the object of providing service life monitoring of a DC link capacitor that can be implemented in a simple and cost-effective manner during operation and implemented cost-effectively.

This object is achieved by the combination of features according to a method for monitoring a DC link capacitor (CZK) in an electrical DC link of a circuit operated on a mains voltage Vac. The circuit comprises: a power factor correction filter and an inverter, the DC link capacitor (CZK), to be monitored, is between the power factor correction filter and the inverter. During the operation of the circuit, the DC link capacitance C of the DC link capacitor (CZK) is determined at least at certain time intervals over the operating time by measuring a power ripple W of a DC link voltage (VZK). The DC link voltage arises at the DC link capacitor (CZK). The power ripple pulses at twice the frequency of the mains voltage. The remaining service life or service life end and/or usability end of the DC link capacitor (CZK) is determined, by an evaluation circuit, from the DC link capacitance C determined in this way, and power of power factor correction filter consumed over a mains half-wave is detected by mains input voltage iₘₐᵢₙₛ that was determined previously in order to regulate the power factor correction filter and the input current iₘₐᵢₙₛ already determined for this purpose.

A basic idea of the disclosure relates to the detection of the condition of the DC link capacitor or the capacitance by measuring the ripple of the DC link voltage, which pulsates at twice the mains frequency due to a likewise pulsating power consumption of the overall circuit composed of PFC and inverter.

The DC link capacitance is preferably determined using a mathematical model by a power measurement and ripple voltage measurement at the DC link capacitor. One of the novel features is that the measurement is performed with the sensors that are present in the EC motor. Thus, no additional circuit technology or sensors are required. Accordingly, this makes cost-effective implementation possible.

The change in the ripple voltage at the DC link capacitor enable conclusions to be drawn about the capacitance and thus the ripple voltage.

To this end, the disclosure proposes a method for monitoring a DC link capacitor in an electrical DC link of a circuit operated on a mains voltage V_{ac}. The circuit comprises a power factor correction filter and an inverter. The DC link capacitor to be monitored is between the power factor correction filter and the inverter. During the operation of the circuit, the DC link capacitance C of the DC link capacitor is determined at least at certain time intervals, over the operating time. This occurs by measuring a power ripple W of a DC link voltage. The DC link voltage arises at the DC link capacitor. The power ripple pulsing is at twice the frequency of the mains voltage. The remaining service life or the service life end and/or usability end of the DC link capacitor is determined, by an evaluation circuit, from the DC link capacitance C determined in this way.

It is particularly advantageous if, in order to determine the DC link capacitance C of the DC link capacitor, a power measurement and a voltage measurement are performed at the DC link capacitor in order to determine the voltage ripple.

It is also advantageous if the method is used to monitor the DC link capacitor of an EC motor that is operated via a motor control circuit with the DC link capacitor. The motor control circuit has a sensor system for operating the EC motor. This sensor system is used simultaneously to detect the power and/or measure the voltage of the voltage ripple at the DC link capacitor. This ensures that no additional circuit technology or sensors are required.

In an especially advantageous embodiment, the power factor correction filter (PFC) is an active power factor correction filter. The power of the power factor correction filter consumed over a mains half-wave is detected by the mains input voltage that was determined previously in order to regulate the power factor correction filter and the input current iₘₐᵢₙₛ, already determined for this purpose.

In an alternative embodiment of the disclosure, the power is measured without knowledge of the mains input voltage V_{ac} by first determining the current i_{D} through a boost diode of the power factor correction filter and then determining the remainder from the following relationship and the detection of the inverter current Iᵢₙᵥ that is flowing as the DC link capacitor current I_{ZK} to the DC link capacitor: I_{ZK}=i_{D}−Iᵢₙᵥ, and the current capacitance value of the DC link capacitor can be determined directly from this by integrating the current I_{ZK} or by determining the charge carriers.

It is also advantageous if the current i_{D} is detected of indirect measurement from the measured mains current by using a duty cycle to calculate the proportion of the current flowing through the boost diode. Alternatively, the current can also be measured directly.

In a likewise advantageous, but alternative embodiment of the disclosure, the DC link capacitance is determined by an observer system. Here, the current i_{D} through a diode and the inverter current Iᵢₙᵥ is performed by measuring the two currents. The difference being regarded as the DC link capacitor current I_{ZK}. It is multiplied by a capacitance value Cₑₛₜ and then integrated. The resulting output voltage U_{ZK_est} at the integrator of the observer system is filtered by a high-pass filter in order to obtain the high-pass-filtered voltage ripple U_{ZK_est, HP} in order to subtract it from a high-pass-filtered mains voltage U_{ZK, mains, HP}. The determined difference ΔU is integrated and given as Cₑₛₜ, whereby an observer/control loop is obtained that tracks the model loopwise to the actually measured capacitor.

A further aspect of the present disclosure also relates to the circuit for monitoring a DC link capacitor in an electrical DC link. It comprises a power factor correction filter and an inverter. The DC link capacitor to be monitored is located between the power factor correction filter and the inverter. An evaluation circuit is designed to carry out the previously described method and, in particular, to acquire or detect physical measured values from the power factor correction filter and the inverter. These are of use when determining the remaining service life or the end of the service life and/or useful life of the DC link capacitor.

Another aspect of the disclosure relates to the fact that the DC link capacitors lose their capacitance over time due to aging, external temperature influences, and self-heating due to ripple currents. In most cases, the end of the capacitor service life is established as when a lower limit of −25% below the initial value of the capacitance is reached.

It is a further aim of the present disclosure to infer the remaining capacitor capacitance from the relationship between load current and voltage ripple. To do this, the mains frequency is determined, the voltage ripple is measured over a mains period, and the load current is measured in the form of the use of the motor current that is already known.

Commensurately intelligent filtering prevents incorrect measurements or external interference from accidentally triggering a message. Furthermore, the evaluation is performed in relation to the initial value of the capacitor, which is why an initializing measurement must be performed at the time of initial start-up.

The disclosure is aimed at measuring the capacitance of the DC link capacitor (electrolyte type) and estimating the remaining service life resulting during operation of the electronics. The concept provides for the calculation of the capacitance by measuring the parameters such as the ripple voltage ΔU_d, load current I_L, and the frequency of the mains voltage f_ac. The relationship can be represented mathematically as follows:

$${C}_{Elko} = \frac{{I}_{L}}{Δ {U}_{d} * 2 * {f}_{a c}}$$

A time-averaging of the calculated capacitance values C_x in combination with the initial value of the capacitance C_0 provides information about the remaining service life of the electrolytic capacitor.

The determination of the DC link capacitance described above optionally results in special configurations of the disclosure, which will be explained in greater detail with reference to FIG. 3.

Other advantageous refinements of the disclosure are characterized in the subclaims and/or depicted in greater detail below together with the description of the preferred embodiment of the disclosure with reference to the figures.

### DRAWINGS

The drawings described herein are for illustrative purposes only of selected embodiments and not all possible implementations and are not intended to limit the scope of the present disclosure.

FIG. 1 is a schematic view of the implementation of a first exemplary embodiment of a circuit topology.

FIG. 2 is a schematic view of the implementation of an alternative exemplary embodiment.

FIG. 3 is a diagram with an explanation of characteristic curves plotted against the voltage.

FIG. 4 is a schematic view of a basic circuit diagram.

FIG. 5 is a schematic view of a flow chart for determining capacitance.

### DETAILED DESCRIPTION

The disclosure will be explained in greater detail below on the basis of the two illustrated exemplary embodiments with reference to FIGS. 1 to 3. The same reference symbols in the figures indicating same structural and/or functional features.

FIG. 1 is a basic circuit diagram of the basic circuit topology of a first exemplary embodiment. Thus, the capacitance and, from this, the service life of a DC link capacitor C_{ZK} can be determined. The circuit 1 includes an active power factor correction filter PFC, that has two inputs E1, E2 connected to a mains voltage supply. In the present exemplary embodiment, the mains voltage supply is a 230 V AG mains voltage.

The circuit 1 also includes an inverter 20. In terms of switching, the inverter 20 is connected to an electronically commutable motor (EC motor) 3. The DC link capacitor C_{ZK}, to be monitored, is located between the power factor correction filter PFC and the inverter 20. Furthermore, the circuit 1 has an evaluation circuit 30 including a microcontroller.

The evaluation circuit 30 receives, from the power factor correction filter PFC, the depicted physical measured quantities mains current IC-mains, mains voltage V-mains, and DC link voltage V_{ZK}. The evaluation circuit 30 also receives the inverter current I_{INV} and the DC link voltage V_{ZK} from the inverter. The description of the exemplary embodiment relates in particular to a system with an active PFC and an EC motor with low dynamic requirements. This means that there are slight changes in torque and speed.

With the specific knowledge of the input voltage V-mains and the input current I-mains, which are already measured by the PFC control, the electrical power consumed by the power factor correction filter PFC over a mains half-wave can be determined. The output of the inverter that drives the EC motor is also known. The power of the inverter 20 is determined via its sensors or from the parameters of the motor control. The electrical power consumed from the grid by the power factor correction filter PFC and the electrical power consumed by the inverter 20 can be assumed to be constant in steady-state operation over a mains period. As a result, there is a quasi-equilibrium between the power consumption of the power factor correction filter PFC from the mains and the power consumption of the inverter 20. However, when considered within a mains half-wave in terms of mains frequency, the electrical power consumed from the voltage mains is dependent on the current and on the voltage and has a sinusoidal square component. The inverter 20 or the EC motor 3 connected to it should ideally have a constant power consumption.

The actual differences in power consumption lead to an energy surplus or energy deficit within a mains period. The difference between the electrical energy consumed and the electrical energy outputted within half a mains period is stored in the DC link capacitor C_{ZK}. This provides an increase or decrease in the DC link voltage V_{ZK} within the specified mains period.

If the voltage offset and the voltage itself are now evaluated, the electrical energy stored in the DC link capacitor C_{ZK} can be calculated using the following formula:

W₁=½C_{ZK}·U_{ZK1}²

W₂=½C_{ZK}·U_{ZK2}²

U_{ZK1} and U_{ZK2} are each the DC link voltage that is obtained from the power factor correction filter PVC, on the one hand, or from the inverter 20.

Since the stored electrical energies are known at any point in time during operation, the value of the capacitance of the DC link capacitor G_{ZK} can be determined by simply rearranging the equations.

In the following, two variants of this basic idea that has been initially described are explained.

In a first option, the method is carried out without an input voltage measurement being performed by the power factor correction filter PFC. If the line voltage is consequently not measured, an estimate can be made about it in the case of sinusoidal line voltage forms. To do this, the current through a boost diode must first be determined. This can be done either directly with the aid of a current measuring circuit or, alternatively, indirectly from the measured mains current I-mains. As described above, the line current I-mains is already transferred from the power factor correction filter PFC to the evaluation circuit 30. Since the diode current 1_{D} flows into the node to the DC link capacitor C_{ZK} and to the inverter 20, the diode current I_{D} is divided into the DC link capacitor current 1_{ZK} and the inverter current I_{INV}.

When measuring the mains current, the duty cycles are used to calculate the current with a view to which specific proportions of the current flows through the boost diode and which proportion flows through the transistor of the power factor correction filter PFC, which is also present.

Thus, after the knowledge of the inverter current I_{INV} has been obtained, the DC link capacitor current I_{ZK}, flowing to the DC link capacitor C_{ZK}, can be calculated by simple subtraction. The capacitance value C of the DC link capacitor C_{ZK} can then be determined by integrating the current or determining the charge carriers.

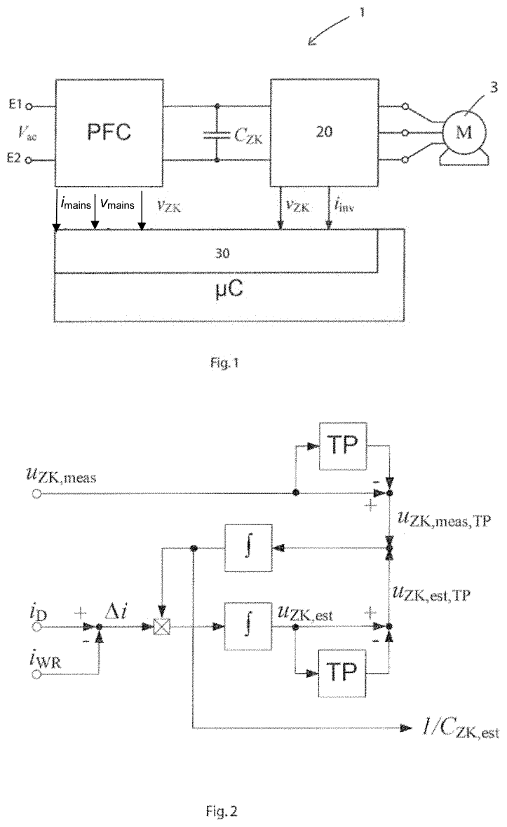

Another alternative method will be described below with reference to FIG. 2. This figure shows an embodiment using a band-pass-filtered observer. This possibility of determining the DC link capacitance of the DC link capacitor C_{ZK} represents a simulation by an observer system, which will be described in greater detail below.

The observer shown in FIG. 2 includes the inputs U_{ZK}, M_{MEAS}, and I_{D} for the diode current and I_{INV} for the inverter current. The current ΔI, which is fed to an integrator of the observer system, is determined from the current differential. The output of this integrator provides the voltage quantity U_{ZK, EST}. This is transferred to a transformer TP of the observer system. A second transformer TP receives the quantity U_{ZK, MEAS} at the input and transfers the quantity U_{ZK, MEAS}, TP at the output to the second integrator after the transformation. The values are fed back to the control loop via the second integrator. The value 1 is outputted after the second integrator by C_{ZK, IST}.

Since ΔI is regarded as the current through the DC link capacitor C_{ZK}, this is multiplied by the value C_{EST} and then integrated. This is in keeping with the calculation rule for a capacitor. The resulting output voltage U_{ZK, EST} at the integrator is filtered by a high-pass filter. For this purpose, a low-pass-filtered component U_{ZKS, TP} is subtracted from U_{ZKS}. The resulting voltage is referred to as U_{ZK, EST, HP}. The voltage U_{ZK, EST} calculated in this manner only has the 100 Hz ripple due to the pulsating power consumption from the mains (at a mains frequency of 50 Hz).

This voltage ripple is subtracted from a high-pass-filtered mains voltage U_{ZK, mains, HP}. The difference ΔU is further integrated.

The ΔU resulting from a deviation of the model from the real DC link capacitor C_{ZK} is thus a measure of how well and exactly the model depicts reality. If ΔU is integrated and specified as C_{EST}, this creates an observer control loop that tracks the model continuously to the actually measured capacitor.

The advantage is that this solution is easy to implement, and no difficult arithmetic operations are required. Furthermore, averaging over a large number of periods is possible, so that one-off disturbances and measurement fluctuations can be compensated for.

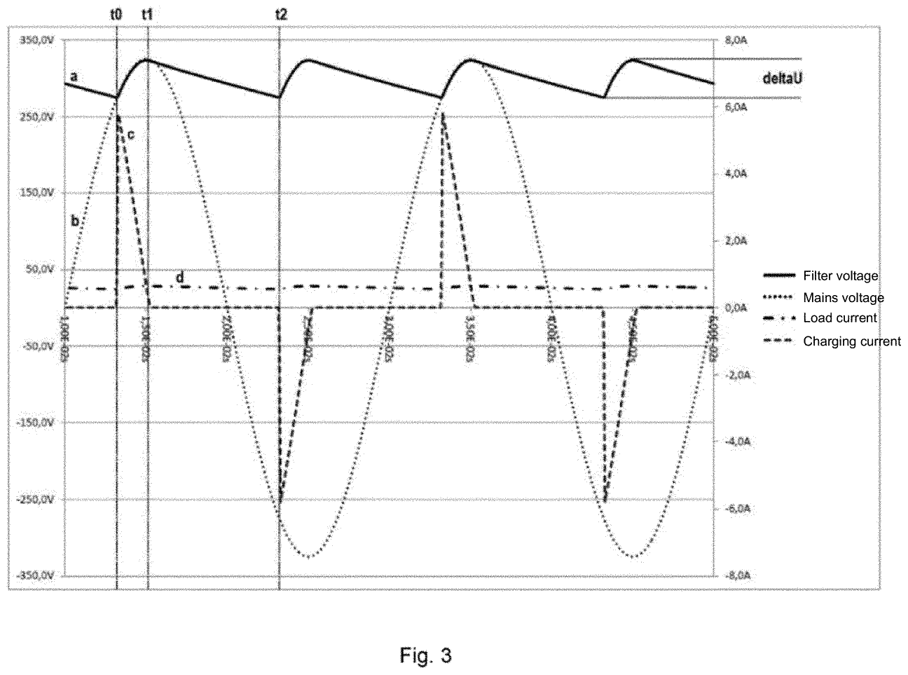

FIG. 3 shows a diagram where, in addition to the ripple voltage ΔU_d (characteristic curve a), the load current I_L (characteristic curve d) and the frequency of the mains voltage f_ac (diagram time difference 2*(t2−t0)) are illustrated.

The average charging current of the DC link capacitor can be calculated backward on the basis of the proportional relationship of capacitance, current, and voltage swing (ripple voltage) together with the times of falling and rising voltage (time differences between t0, t1, and t2) using the following formula:

$${I}_{Ladestrom , Mittel \_ t0 / t 1} = \frac{{C}_{Elko} * Δ {U}_{d}}{Δ t} mit Δ t = t 1 - t 0 und Δ {U}_{d} = delta U$$

The mean RMS charging current from the mains over the entire mains period then follows from I_{charging current}*Δt_{recharging time}/t_{mains period}.

If the operating circuit at the mains input has an NTG to limit the inrush current or other resistors (as intended or even parasitic), the unknown voltage drop across these resistors means that no precise back-calculation to the mains voltage can be made using the following equation:

$${U}_{mains voltage} = \frac{{U}_{D C link}}{\sqrt{2}}$$

In order to get an exact determination of the mains voltage from the known DC link voltage value, 2 diode sections in the bridge rectification (˜2*0.8V=1.6V) as well as the voltage drop across the resistors in the input circuit would have to be taken into account.

The voltage drop across the resistors in the input circuit can now be determined using the recharge current calculated above and a table of ambient temperature and current via the mains input components stored in the microcontroller. The latter table or data sets are needed in order to compensate for the temperature dependency of the resistances in the input circuit (e.g., with NTG) due to self-heating or ambient temperature.

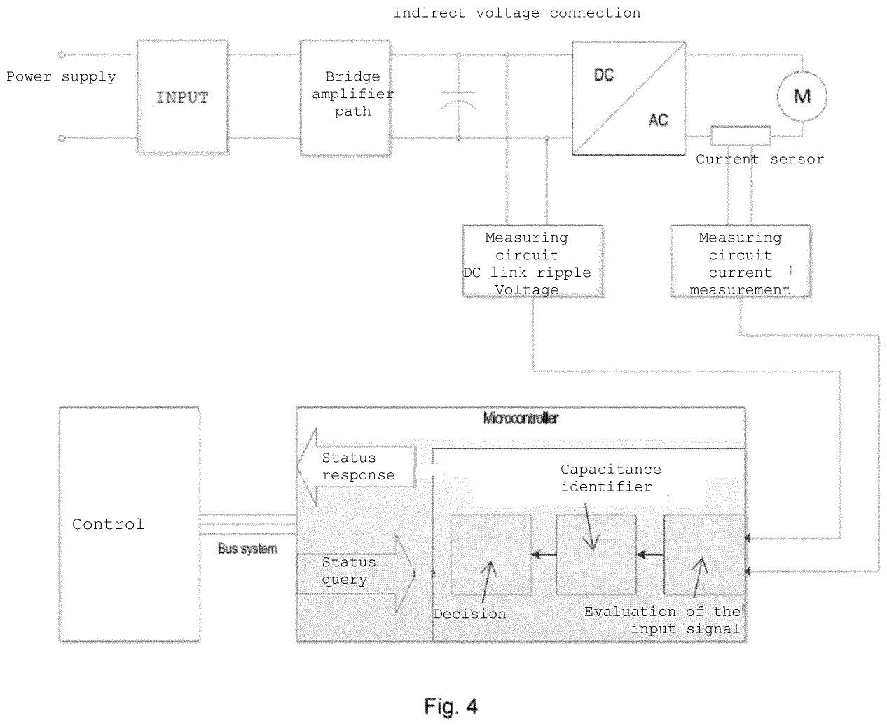

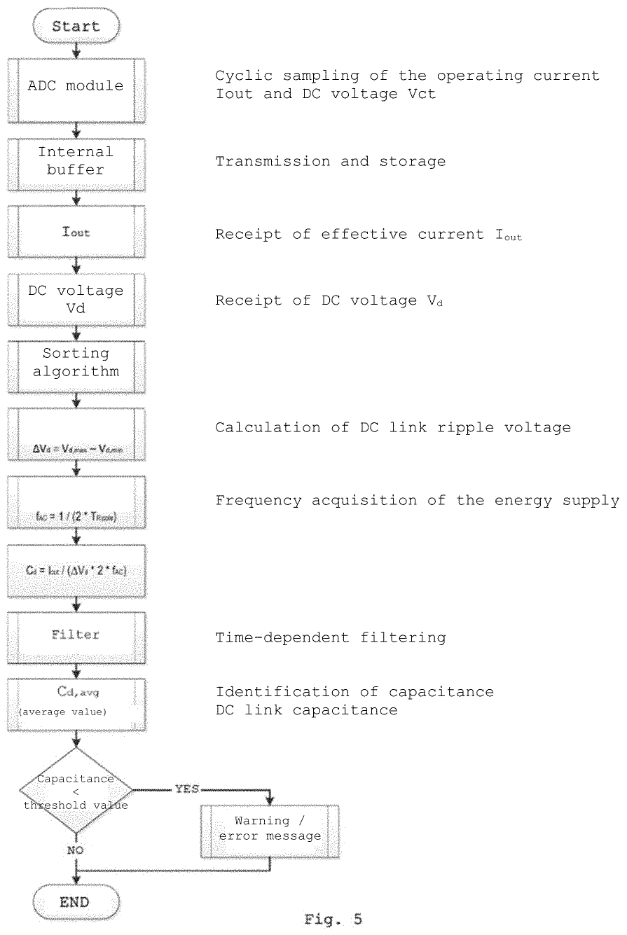

Early failure detection by measuring the residual capacitance of the DC link capacitor is a method where the past (running time, temperature, ripple current load) and its effect on the capacitor are considered. A combined ripple current of the capacitor can be calculated with the optionally calculated recharging current and the motor current, which is also known from current measurement. Together with the ambient temperature from another, optional temperature sensor, a forward-looking calculation of the remaining service life can be performed if the operating point (temperature and power) is assumed to be constant. A corresponding exemplary embodiment of a basic circuit diagram can be found in FIG. 4, and a flowchart for determining the capacitance can be found in FIG. 5.

The disclosure is not limited in its execution to the abovementioned preferred exemplary embodiments. Rather, a number of variants are conceivable that make use of the illustrated solution even in the form of fundamentally different embodiments.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1.-8. (canceled)

9. A method for monitoring a DC link capacitor (C_{ZK}) in an electrical DC link of a circuit operated on a mains voltage V_{ac}, the circuit comprising:
a power factor correction filter and an inverter,
the DC link capacitor (C_{ZK}), to be monitored, is between the power factor correction filter (PFC) and the inverter,
during the operation of the circuit, the DC link capacitance C of the DC link capacitor (C_{ZK}) is determined at least at certain time intervals over the operating time by measuring a power ripple W of a DC link voltage (VZK), which DC link voltage arises at the DC link capacitor (C_{ZK}), the power ripple pulsing at twice the frequency of the mains voltage; and
remaining service life or the service life end or usability end of the DC link capacitor (C_{ZK}) is determined, by an evaluation circuit, from the DC link capacitance C determined in this way, and power of power correction filter consumed over a mains half-wave is detected by mains input voltage iₘₐᵢₙₛ that was determined previously in order to regulate the power factor correction filter and input current iₘₐᵢₙₛ already determined for this purpose.

10. The method as set forth in claim 9, wherein, in order to determine the DC link capacitance C of the DC link capacitor (C_{ZK}), a power measurement and a voltage measurement are performed at the DC link capacitor (C_{ZK}) in order to determine the voltage ripple.

11. The method as set forth in claim 9, wherein the method is used to monitor the DC link capacitor of an EC motor that is operated via a motor control circuit having the DC link capacitor, the motor control circuit having a sensor system for operating the EC motor, and this sensor system is used simultaneously to detect the power and/or measure the voltage of the voltage ripple at the DC link capacitor (C_{ZK}).

12. The method as set forth in claim 11, where the power is measured without knowledge of the mains input voltage V_{ac} by first determining the current i_{D} through a boost diode of the power factor correction filter (PFC) and then determining the remainder from the following relationship and the detection of the inverter current Iᵢₙᵥ that is flowing as the DC link capacitor current I_{ZK} to the DC link capacitor (C_{ZK}):I_{ZK}=i_{D}−Iᵢₙᵥ, and the current capacitance value of the DC link capacitor (C_{ZK}) can be determined directly from this by integrating the current I_{ZK} or by determining the charge carriers.

13. The method as set forth in claim 12, wherein the current i_{D} is detected by indirect measurement from the measured mains current by using a duty cycle to calculate the proportion of the current flowing through the boost diode.

14. The method as set forth in claim 9 where the DC link capacitance is determined by an observer system, current i_{D} through a diode and the inverter current Iᵢₙᵥ is performed by measuring the two currents, the difference being regarded as the DC link capacitor current I_{ZK}, and this is multiplied by a capacitance value Cₑₛₜ and then integrated, and the resulting output voltage U_{ZK_est} at the integrator of the observer system is filtered by a high-pass filter in order to obtain the high-pass-filtered voltage ripple U_{ZK_est, HP}, and the determined difference ΔU is integrated and given as Cₑₛₜ, whereby an observer/control loop is obtained which tracks the model loopwise to the actually measured capacitor.

15. An electrical circuit for monitoring a DC link capacitor (C) in an electrical DC link of a circuit operated on a mains voltage _{Vac}, the circuit comprising:
a power factor correction filter and an inverter;
the DC link capacitor (C_{ZK}), to be monitored, being between the power factor correction filter and the inverter; and
an evaluation circuit to acquire or detect physical measured values from the power factor correction filter and the inverter and, during operation of the circuit, the DC link capacitance C of the DC link capacitor (C_{ZK}) is determined at least at certain time intervals over the operating time by measuring a power ripple W of a DC link voltage (C_{ZK}) for power ripple pulsing at twice the frequency of the mains voltage, and remaining service life or service life end and/or usability end of the DC link capacitor (C_{ZK}) is determined from the DC link capacitance C.
